(19) United States
(12) Patent Application Publication
(10) Pub. No.: US 2015/0034008 A1
(43) Pub. Date: Feb. 5, 2015

(54) VAPOR DEPOSITION APPARATUS

(71) Applicant: Samsung Display Co., Ltd., Yongin-city (KR)

(72) Inventors: Choel-Min JANG, Yongin-city (KR); Myung-Soo Huh, Yongin-city (KR); Suk-Won Jung, Yongin-city (KR); Sung-Hun Key, Yongin-city (KR); In-Kyo Kim, Yongin-city (KR)

(73) Assignee: Samsung Display Co., Ltd., Yongin-city (KR)

(21) Appl. No.: 14/183,963

(22) Filed: Feb. 19, 2014

(30) Foreign Application Priority Data
Aug. 2, 2013 (KR) 10-2013-0092246

(51) Int. Cl. C23C 16/52; C23C 16/455

(52) U.S. Cl. CPC C23C 16/52; C23C 16/455
USPC 118/712; 118/715

(57) ABSTRACT

Provided is a vapor deposition apparatus including a deposition unit including a plurality of deposition modules disposed parallel to each other and a substrate mounting unit located below the deposition unit, on which a substrate is mounted. In this case, each of the plurality of deposition modules includes a nozzle configured to selectively inject a raw gas and a purge gas toward the substrate mounting unit, and the nozzle injects the raw gas while the substrate mounting unit is being located below the nozzle.

### CROSS REFERENCE TO RELATED APPLICATION

This application claims the benefit of Korean Patent Application No. 10-2013-0092246, filed on Aug. 2, 2013, in the Korean Intellectual Property Office, which is hereby incorporated by reference for all purposes as if fully set forth herein.

### BACKGROUND

1. Field

Exemplary embodiments of the present invention relate to a vapor deposition apparatus, and, more particularly, to a vapor deposition apparatus that reduces the length of a chamber of the vapor deposition apparatus.

2. Discussion of the Background

Semiconductor devices, display apparatuses, and other electronic devices typically include a plurality of thin films. Of the various methods of forming the plurality of thin films, one of them is a vapor deposition method.

The vapor deposition method uses one or more gases as a raw material for forming thin films. Vapor deposition methods include chemical vapor deposition (CVD), atomic layer deposition (ALD), and various other related methods.

According to the ALD vapor deposition method, one raw material is injected onto a substrate and then purged and pumped. In this way, single molecular layer layers may be formed. Then, another raw material is injected onto the substrate and then purged and pumped to finally form a desired single atomic layer or a plurality of atomic layers.

FIG. 1 is a schematic view illustrating a general atomic layer deposition apparatus 10. The atomic layer deposition apparatus 10 may include a deposition unit 11 and a substrate mounting unit 20 located below the deposition unit 11, on which a substrate S is mounted.

The deposition unit 11 may include a plurality of deposition modules M, and the deposition modules M continuously inject a raw gas toward the substrate S. In this case, the substrate S reciprocates below the deposition unit 11, thereby forming a thin film on the substrate S.

When assuming a width of the substrate S and a width of the deposition unit 11 are identical to each other as L1, to allow a thin film to be formed on the entirety of substrate S, the substrate S should be transferred not only to a region \textcircled{1} but also to regions \textcircled{2} and \textcircled{3}.

Also, since the deposition unit 11 continuously injects a raw gas, plates 21 and 22 are formed on both sides of the substrate mounting unit 20. Although the substrate S is not disposed under the deposition unit 11, that is, although the substrate S is located in one of the regions \textcircled{2} and \textcircled{3}, the raw gas is injected to a bottom of a chamber (not shown), thereby preventing pollution of a driving unit, etc, located in the chamber.

Since the plates 21 and 22 exist, the chamber is extended to include regions \textcircled{4} and \textcircled{5} to transfer the substrate mounting unit 20. That is, a size of the chamber becomes 5×L1 that is five times of a width of the substrate S. Additionally, as a size of substrates S increase according to a recent trend of enlarged display apparatuses, the size of the chamber should be increased.

### BRIEF SUMMARY OF THE INVENTION

Exemplary embodiments of the present invention provide a vapor deposition apparatus capable of reducing a length of a chamber.

Additional aspects will be set forth in part in the description which follows and, in part, will be apparent from the description, or may be learned by practice of the presented embodiments.

According to exemplary embodiments of the present invention, a vapor deposition apparatus includes a deposition unit including a plurality of deposition modules disposed in parallel and a substrate mounting unit located below the deposition unit, on which a substrate is mounted, wherein each of the plurality of deposition modules includes a nozzle configured to selectively injecting a raw gas and a purge gas toward the substrate mounting unit and the nozzle injects the raw gas while the substrate mounting unit is being located below the nozzle.

According to exemplary embodiments of the present invention, a vapor deposition apparatus includes a deposition unit including a plurality of deposition modules disposed in parallel, a substrate mounting unit located below the deposition unit, on which a substrate is mounted, a sensor unit configured to sense a position of the substrate mounting unit, and a control unit configured to receive position information of the substrate mounting unit from the sensor unit. In this case, each of the plurality of deposition modules includes a nozzle configured to selectively injecting a raw gas and a purge gas toward the substrate mounting unit, one end of the nozzle is connected to a switch unit configured to selectively supply the raw gas and the purge gas, and the control unit is configured to control an operation of the switch unit according to the position information.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a cross-sectional view schematically illustrating a general vapor deposition apparatus.

FIG. 2 is a schematic cross sectional view illustrating a vapor deposition apparatus according to an exemplary embodiment of the present invention.

FIG. 3 is an enlarged view illustrating ‘A’ of FIG. 2.

FIGS. 4 and 5 are schematic views illustrating exemplary embodiments of a nozzle and a switch unit of the vapor deposition apparatus of FIG. 2, respectively.

FIGS. 6 and 7 are schematic views illustrating other exemplary embodiments of the nozzle and the switch unit of the vapor deposition apparatus of FIG. 2, respectively.

FIG. 8 is a schematic cross-sectional view illustrating an organic light emitting display apparatus manufactured by using the vapor deposition apparatus of FIG. 2; and

FIG. 9 is an enlarged view illustrating ‘F’ of FIG. 8.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

Since the present invention may have various modifications and several embodiments, exemplary embodiments are shown in the drawings and will be described in detail. However, this is not to limit the present invention to the exemplary embodiments but should be understood as including all modifications, equivalents, and substitutes included in the spirit and the scope of the present invention. While describing the embodiments, when it is determined that a detailed description of well-known typical art may make the points of the present embodiment unclear, the detailed description thereof will be omitted.

It will be understood that although the terms “first”, “second”, etc. may be used herein to describe various components, these components should not be limited by these terms. These terms are only used to distinguish one component from another.

Terms are used herein only to describe the exemplary embodiments but not to limit the present invention. Singular expressions, as not clearly described to be different in contexts, include plural expressions. In the present specification, terms of “comprise” or “have” are used to designate features, numbers, steps, operations, elements, components or combinations thereof disclosed in the specification as being present but not to exclude possibility of the existence or the addition of one or more other features, numbers, steps, operations, elements, components, or combinations thereof.

Hereinafter, the exemplary embodiments of the present invention will be described in detail with reference to the attached drawings.

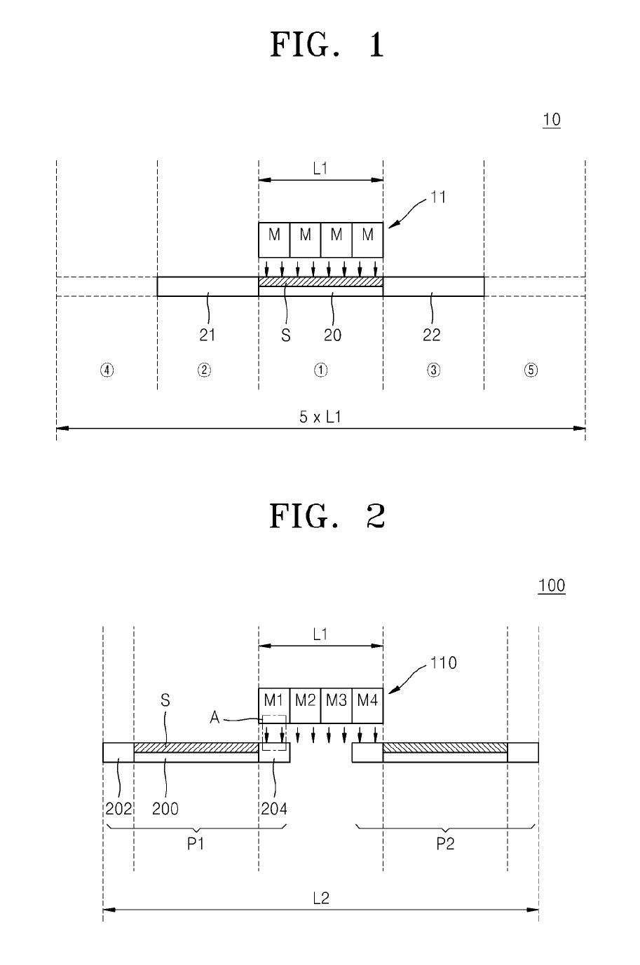

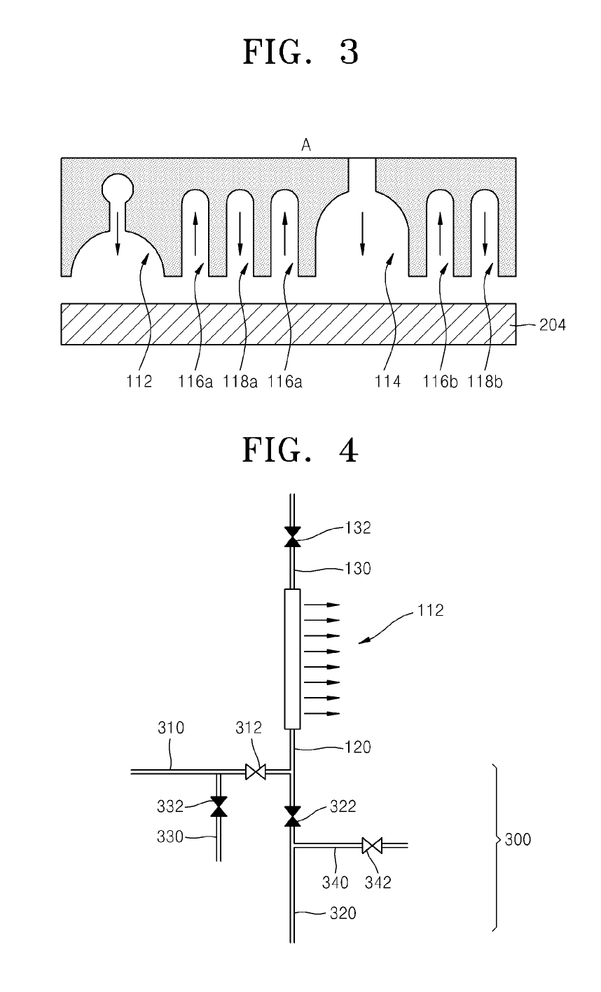

FIG. 2 is a cross-sectional view illustrating a vapor deposition apparatus 100 according to an embodiment of the present invention, and FIG. 3 is an enlargement view illustrating ‘A’ of FIG. 2.

Referring to FIGS. 2 and 3, the vapor deposition apparatus 100 may include a deposition unit 110 and a substrate mounting unit 200 located below the deposition unit 110, on which a substrate S is mounted. Also, the vapor deposition apparatus 100 may include a chamber (not shown) that may contain some or all of the apparatus shown in FIG. 2.

The chamber may be connected to a pump (not shown) to control a pressure atmosphere of a deposition process and may include one or more gates (not shown) for allowing the substrate S to enter and exit. Also, the chamber may include a driving unit (not shown) for transferring the substrate S to different positions within the chamber.

The deposition unit 110 may include a plurality of deposition modules M1 to M4 disposed in parallel. The deposition unit 110, in FIG. 2, includes a first deposition module M1, a second deposition module M2, a third deposition module M3, and a fourth deposition module M4, but is not limited thereto and may include various numbers of deposition modules.

Each of the plurality of deposition modules M1 to M4 may supply one or more raw gases for forming a thin film on the substrate S toward the substrate mounting unit 200. Further, each of the plurality of deposition modules M1 to M4 may include nozzles 112 and 114 selectively injecting a raw gas and a purge gas toward the substrate mounting unit 200.

For example, the nozzles 112 and 114 may inject the raw gas toward the substrate mounting unit 200 when the substrate mounting unit 200 is located below the nozzles 112 and 114 and may inject the purge gas when the substrate mounting unit 200 is transferred and is not located below the nozzles 112 and 114.

For this, one end of the nozzles 112 and 114 may be connected to a switch unit 300 (refer to FIG. 4) configured to selective supply the raw gas and the purge gas to the nozzles 112 and 114. Also, the vapor deposition apparatus 100 may include a sensor unit (not shown) configured to sense a position of the substrate mounting unit 200 and a control unit (not shown) configured to receive position information of the substrate mounting unit 200 from the sensor unit and further configured to control operation of the switch unit 300 according to the position information. It will be described below with reference to FIGS. 4 to 7.

The nozzles 112 and 114 included in each of the plurality of deposition modules M1 to M4 may include a first nozzle 112 and a second nozzle 114.

The first nozzle 112 may selectively inject a first raw gas and the purge gas toward the substrate mounting unit 200, and the second nozzle 114 may selectively inject a second raw gas and the purge gas toward the substrate mounting unit 200.

Each of the plurality of deposition modules M1 to M4 may further include an exhaust part 116a and a purge part 118a disposed between the first nozzle 112 and the second nozzle 114.

The purge part 118a discharges the purge gas toward the substrate S. The purge gas may be a gas having no effect on deposition, for example, argon or nitrogen gas. The exhaust part 116a exhausts byproducts separated from the substrate S by the purge part 118a and extra gases. The exhaust part 116a, as shown in FIG. 3, may be located on both sides of the purge part 118a but is not limited thereto.

The substrate mounting unit 200 may include a fastening element (not shown) to allow the substrate to be fastened. The fastening element may be a clamp, a pressing element, an adhesive material, or any other fastening element. The substrate mounting unit 200 may reciprocate below the deposition unit 110 during a deposition process, thereby controlling a thickness of a thin film deposited on the substrate S. The substrate mounting unit 200 may include a first plate 202 and a second plate 204 extending from both sides of the substrate mounting unit 200. However the device is not limited to this embodiment and one having skill in the art would appreciate alternative embodiments. For example, in another embodiment, deposition unit 110 may reciprocate above substrate mounting unit 200. In another exemplary embodiment, the substrate itself may reciprocate below deposition unit 110. In still another exemplary embodiment, both substrate mounting unit 200 and deposition unit 110 may reciprocate. Additionally, the vapor deposition apparatus may be configured to operate in a number of positions not shown in the figures; for example, along vertical or horizontal axes.

Hereinafter, a method of forming a thin film on the substrate S by using the deposition unit 110 will be described with reference to FIGS. 2 and 3. Additionally, an example in which an AlxOy thin film is formed on the substrate S while the substrate mounting unit 200 is transferred from a position P1 to a position P2 in FIG. 2, will be described below.

When the substrate mounting unit 200 mounted with the substrate S is located in the position P1, the second plate 204 of the substrate mounting unit 200 may be located below the first deposition module M1 before the substrate S is located below the module M1. According thereto, the first nozzle 112 of the first deposition module M1 may start injecting the first raw gas toward the substrate mounting unit 200.

The first nozzle 112 starts injecting the first raw gas due to the second plate 204 before the substrate S is located below the first nozzle 112. Because of this, pressure in the first nozzle 112 may be uniformly maintained, so pressure in the first nozzle 112 is prevented from rapidly changing while discharging the first raw gas onto the substrate S, thereby evenly discharging the first raw gas onto the substrate S.

Since the second plate 204 is located below the first deposition module M1, the second nozzle 114 may start injecting the second raw gas toward the substrate mounting unit 200. In this case, the first nozzle 112 and the second nozzle 114 may operate at the same time or may operate independently from each other.

For example, when the sensor units configured to sense the position of the substrate mounting unit 200 are installed in the first nozzle 112 and the second nozzle 114, the first nozzle 112 and the second nozzle 114 may operate independently. That is, as the substrate mounting unit 200 is transferred to the position P2, the first nozzle 112 and the second nozzle 114 may operate sequentially.

However, when the sensor unit is mounted on each of the plurality of deposition modules M1 to M4 or is mounted on an arbitrary position in the chamber to sense whether the substrate mounting unit 200 is located below each of the deposition modules M1 to M4 or not, the control unit may control operations of the plurality of deposition modules M1 to M4, respectively, based on the position information of the substrate mounting unit 200 sensed by the sensor unit. That is, the first nozzle 112 and the second nozzle 114 included in each of the plurality of deposition modules M1 to M4 may operate at the same time.

On the other hand, when the substrate mounting unit 200 is located in the position P1, the first nozzle 112 and the second nozzle 114 included in each of the second deposition module M2, the third deposition module M3, and the fourth deposition module M4, below which the substrate mounting unit 200 is not located, inject the purge gas.

The substrate mounting unit 200 is transferred from the position P1 to the position P2 in such a way that the first raw gas is injected onto the substrate S by the first nozzle 112 of the first deposition module M1. The first raw gas may be a gas containing A1 atoms, for example, gaseous trimethyl aluminum (TMA). Through this process, an adsorption layer containing A1 is formed on a top surface of the substrate S, in which the adsorption layer may include a chemical adsorption layer and a physical adsorption layer.

The adsorption layer formed on the top surface of the substrate S, also called the physical adsorption layer, which has a low binding force between molecules, is separated from the substrate S by the purge gas injected by the first purge part 118a located next to the first nozzle 112 based on a progress direction of the substrate S. Also, the physical adsorption layer separated from the substrate S may be effectively removed from the substrate S by pumping of the first exhaust part 116a located next to the first nozzle 112 based on the movement direction of the substrate S during position transfer.

When the substrate S is disposed under the second nozzle part 114 of the first deposition module M1, the second raw gas is injected through the second nozzle 114 toward the substrate S. The second raw gas may contain radicals. For example, the second raw gas may include oxygen radicals. The oxygen radicals may be formed by injecting H₂O, O₂, N₂O, etc. into a plasma generation part (not shown) of the second nozzle 114.

The second raw gas may react with the chemical adsorption layer formed by the first raw gas previously adsorbed onto the substrate S or may substitute a part of the chemical adsorption layer, thereby finally forming a desired deposition layer, for example, an AlxOy layer. An excess of the second raw gas may form the physical adsorption layer and may remain on the substrate S.

The physical adsorption layer formed from the second raw gas remaining on the substrate S may be separated from the substrate S by purge gas injected by a second purge part 118b located next to the second nozzle 114 based on the progress direction of the substrate S during transfer and may be effectively removed from the substrate S by pumping of a second exhaust part 116b located next to the second nozzle 114 based on the progress direction of the substrate S.

Accordingly, while the substrate S is passing through a bottom of the first deposition module M1, a desired single atomic layer may be formed on the substrate S. Also, when the substrate mounting unit 200 is transferred to the position P2, for example, four deposition processes are performed on the substrate S. The substrate mounting unit 200 reciprocates between the positions P1 and P2, thereby forming a thin film having a desired thickness on the substrate S.

When the substrate mounting unit 200 is located in the position P2, since the substrate mounting unit 200 is not located below the first deposition module M1, the second deposition module M2, and the third deposition module M3, the first nozzle 112 and the second nozzle 114 included in each of the first deposition module M1, the second deposition module M2, and the third deposition module M3 inject the purge gas.

That is, since the deposition unit 110 may intermittently supply the raw gas according to the position of the substrate mounting unit 200, an amount of consumed raw gas may be reduced, thereby increasing the durability of the first and second nozzles 112 and 114.

Also, since lengths of the first plate 202 and the second plate 204 formed to prevent the driving unit in the chamber from being polluted by the raw gas may be shortened, the overall length of the chamber L2 may also be reduced.

For example, when a distance between the substrate S and the deposition unit 110 is identical (L1), the deposition unit 110 includes the four deposition modules M1 to M4, and a length of the first plate 202 and the second plate 204 is corresponding to a width of one deposition module, the length L2 of the chamber of FIG. 2 may be reduced 70% or less of a normal length of the chamber (L1×5 of FIG. 1).

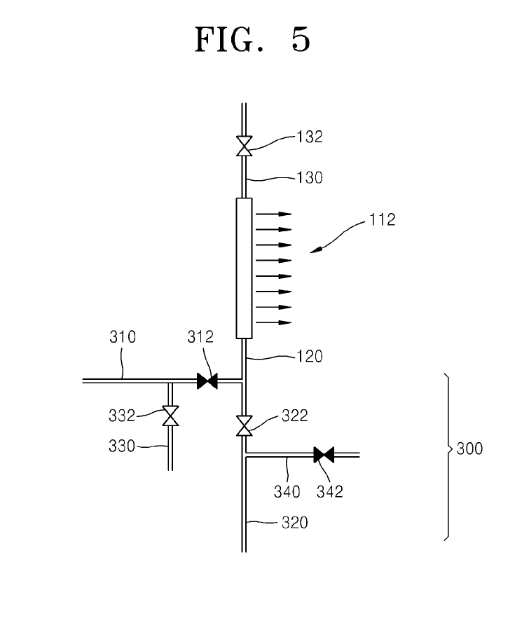

FIGS. 4 and 5 are schematic views illustrating examples of the nozzle 112 and the switch unit 300 of the vapor deposition apparatus 100, respectively.

In FIGS. 4 and 5, the first nozzle 112 is shown. The second nozzle 114 has same configuration as that of the first nozzle 112.

Referring to FIGS. 4 and 5, one end of the first nozzle 112 is connected to an inflow pipe 120 and another end of the first nozzle 112 is connected to a discharge pipe 130. Additionally, the inflow pipe 120 may be connected to the switch unit 300 and the discharge pipe 130 may be formed with a discharge valve 132. Operations of the switch unit 300 and the discharge valve 132 may be controlled by the control unit according to the position information of the substrate mounting unit 200 sensed by the sensor unit.

The switch unit 300 may include a raw gas pipe 310 connected to the inflow pipe 120 and a purge gas pipe 320. The raw gas pipe 310 may be formed to include a raw gas valve 312 for blocking a flow of the raw gas, and the purge gas pipe 320 may be formed to include a purge gas valve 322 for blocking a flow of the purge gas. Since the switch unit 300 selectively supplies the raw gas and the purge gas to the inflow pipe 120, the raw gas valve 312 and the purge gas valve 322 may alternatively operate.

Also, the switch unit 300 may further include a first vent pipe 330 diverged from the raw gas pipe 310 and a second vent pipe 340 diverged from the purge gas pipe 330. A first valve 332 may be disposed on the first vent pipe 330, and a second valve 342 may be disposed on the second vent pipe 340.

FIG. 4 is a view illustrating a case in which the switch unit 300 supplies the first raw gas to the first nozzle 112. Referring to FIG. 4, the raw gas valve 312 is open and the purge gas valve 322 and the first valve 332 are closed. As a result thereof, the first raw gas may be supplied to the first nozzle 112 through the raw gas pipe 310 and the inflow pipe 120. In this case, the discharge valve 132 disposed on the discharge pipe 130 is closed. Accordingly, the first raw gas supplied to the first nozzle 112 may be injected by the first nozzle 112 toward the substrate mounting unit 200.

On the other hand, the second valve 342 is open while the first raw gas is being supplied, thereby discharging the purge gas supplied to the purge gas pipe 320 through the second vent pipe 340. That is, the second valve 342 and the purge gas valve 322 may alternatively operate.

In FIG. 5, the switch unit 300 supplies the purge gas to the first nozzle 112. Opposite to FIG. 4, the raw gas valve 312 and the second valve 342 are closed (OFF) and the purge valve 322 is open (ON). Accordingly, the purge gas may be supplied to the first nozzle 112 through the purge gas pipe 320 and the inflow pipe 120.

In this case, the discharge valve 132 disposed on the discharge pipe 130 is open, and the purge gas allows the first raw gas in the first nozzle 112 to be purged, while also being injected toward the substrate mounting unit 200, and being discharged through the discharge pipe 130, thereby reducing a degree of pollution of the first nozzle 112.

Since the discharge valve 132 is open while the purge gas is being supplied to the first nozzle 112, pressure in the first nozzle 112 while the purge gas is being supplied may be smaller than pressure in the first nozzle 112 while the first raw gas is being supplied. That is, when replacing the purge gas by the first raw gas to be supplied to the first nozzle 112, the pressure in the first nozzle 112 may be changed, which may have an effect on forming a thin film.

According to the present embodiment, as described above, before performing the deposition process on the substrate S, the first plate 202 or the second plate 204 is first located below the first nozzle 112, thereby supplying the first raw gas to the first nozzle 112 and closing the discharge valve 132. Accordingly, before the substrate S is located below the first nozzle 112, the pressure in the first nozzle 112 may be uniformly maintained as pressure necessary for injecting the first raw gas.

Since the first valve 322 is open while the purge gas is being supplied to the first nozzle 112, the first raw gas supplied to the raw gas pipe 310 is discharged through the first vent pipe 330. That is, the first valve 322 and the raw gas valve 312 alternatively operate.

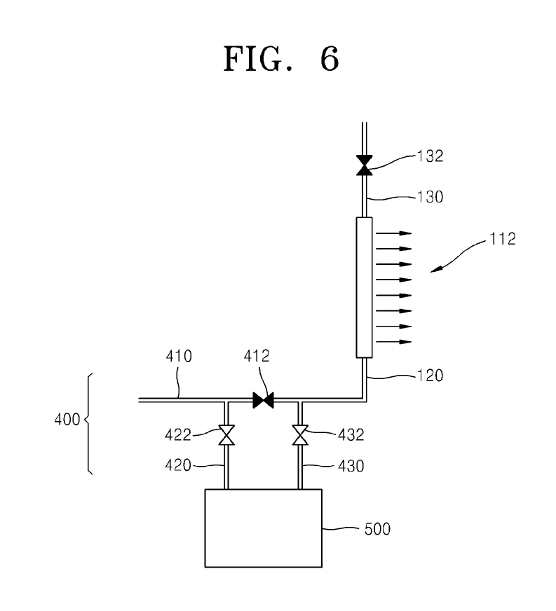

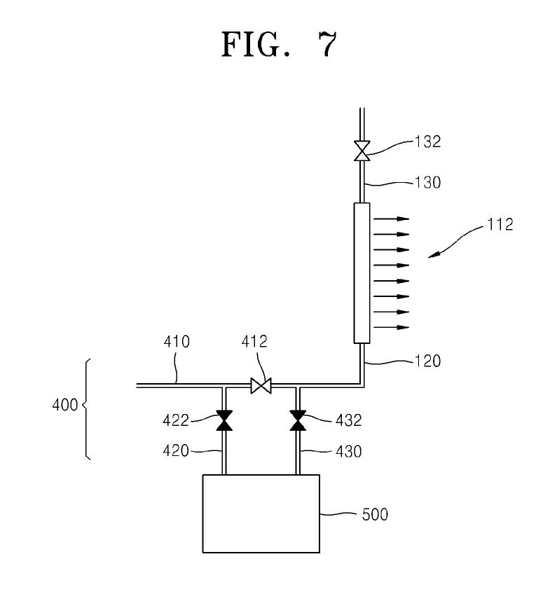

FIGS. 6 and 7 are schematic views illustrating other examples of the first nozzle 112 and the switch unit 300 of the vapor deposition apparatus 100, respectively.

In FIGS. 6 and 7, the first nozzle 112 is shown. However, the second nozzle 114 has same configuration as that of the first nozzle 112.

Referring to FIGS. 6 and 7, one end of the first nozzle 112 is connected to an inflow pipe 120 and another end of the first nozzle 112 is connected to the discharge pipe 130. Also, the inflow pipe 120 may be connected to the switch unit 400 and the discharge pipe 130 may be formed having the discharge valve 132. The control unit may control operations of the switch unit 400 and the discharge valve 132 according to position information of the substrate mounting unit 200 sensed by the sensor unit.

The switch unit 400 may include a purge gas pipe 410 connected to the inflow pipe 120, a first pipe 420 diverged and extended from the purge gas pipe 410, and a second pipe 430. The first pipe 420 and the second pipe 430 may be connected to a canister 500 that supplies the first raw gas to the inflow pipe 120.

A purge gas valve 412 for blocking a flow of the purge gas may be formed on the purge gas pipe 410. Since the purge gas valve 412 is located between the first pipe 420 and the second pipe 430, the purge gas may directly flow into the inflow pipe 120 or may flow into the inflow pipe 120 via the canister 500, depending on whether the purge gas valve 412 is open or not.

The first pipe 420 is formed with a first valve 422 and the second pipe 430 is formed with a second valve 432. The first valve 422 and the second valve 432 may operate contrary to the purge gas valve 412.

For example, as shown in FIG. 6, while the first raw gas is being supplied to the inflow pipe 120, the purge gas valve 412 is closed and the first valve 422 and the second valve 432 are open, thereby allowing the purge gas to pass through the canister 500. When the canister 500 supplies the first raw gas, the purge gas may function as a carrier gas for carrying the first raw gas.

In this case, the discharge valve 132 is closed. That is, the discharge valve 132 operates contrary to the first valve 422 and the second valve 432, thereby allowing the first raw gas to be injected by the first nozzle 112 toward the substrate mounting unit 200.

However, as shown in FIG. 7, while the purge gas is being supplied to the inflow pipe 120, the first valve 422 and the second valve 432 are closed and the purge gas valve 412 and the discharge valve 132 are open, thereby not only injecting the purge gas toward the substrate mounting unit 200 but also discharging the purge gas through the discharge pipe 130.

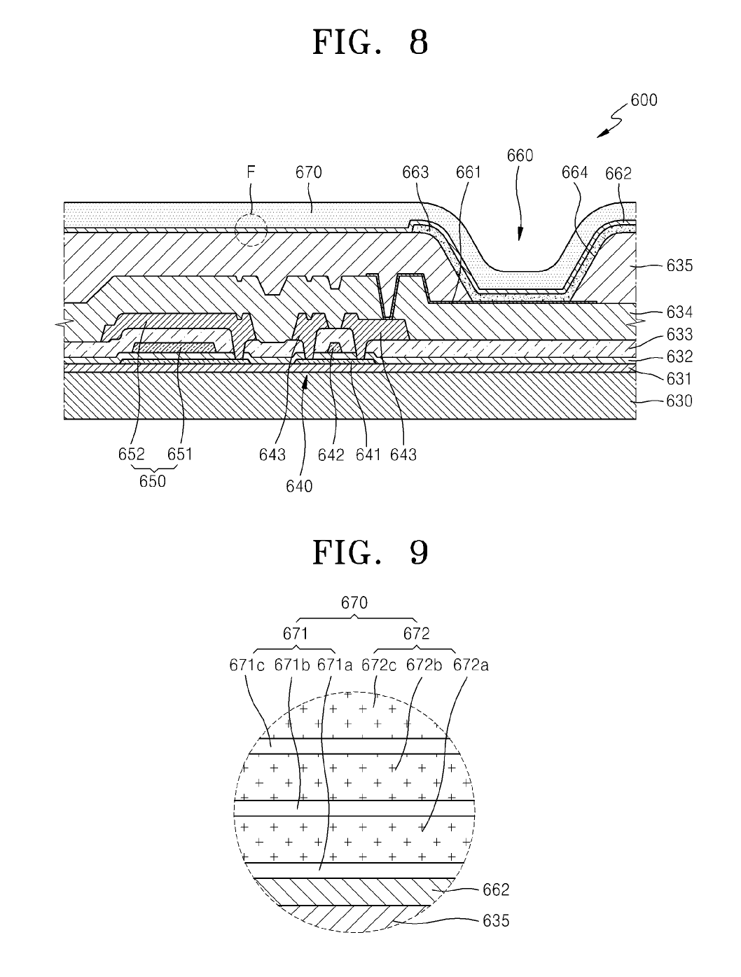

FIG. 8 is a schematic cross-sectional view illustrating an organic light emitting display apparatus 600 manufactured by using the vapor deposition apparatus 100, and FIG. 9 is an enlarged view illustrating ‘F’ shown in FIG. 8.

Referring to FIGS. 8 and 9, the organic light emitting display apparatus 600 is formed on a substrate 630. The substrate 630 may be formed of one of a glass material, a plastic material, and a metallic material.

A flat surface is provided on a top of the substrate 630, and a buffer layer 631 containing an insulating material to prevent penetration of water and foreign bodies is formed toward the substrate 630.

On the buffer layer 631, a thin film transistor (TFT) 640, a capacitor 650, and an organic light emitting device (OLED) 660 are formed. The TFT 640, largely, includes an active layer 641, a gate electrode 642, and source/drain electrodes 643. The OLED 660 includes a first electrode 661, a second electrode 662, and an intermediate layer 663. The capacitor 650 includes a first capacitor electrode 651 and a second capacitor electrode 652.

In detail, the active layer 641 formed as a certain pattern is disposed on a top surface of the buffer layer 631. The active layer 641 may contain one of an inorganic semiconductor material such as silicon, an organic semiconductor material, and an oxide semiconductor material and may be formed by injecting a p-type or n-type dopant. The first capacitor electrode 651 is formed on the same layer as the active layer 641 and may be formed of a material identical to that forming the active layer 641.

A gate insulating layer 632 is formed on a top of the active layer 641. The gate electrode 642 is formed on a top of the gate insulating layer 632 to correspond to the active layer 641. An interlayer dielectric 633 is formed to cover the gate electrode 642, and the source/drain electrodes 643 are formed on the interlayer dielectric 633 to be in contact with a certain area of the active layer 641. The second capacitor electrode 652 is formed on the same layer as the source/drain electrodes 643 and may be formed of a material identical to that forming the source/drain electrodes 643.

A passivation layer 634 is formed to cover the source/drain electrodes 643, and an additional insulating layer may further be formed on a top of the passivation layer 634 to planarize the TFT 640.

The first electrode 661 is formed on the passivation layer 634. The first electrode 661 may be formed to be electrically connected to any one of the source/drain electrodes 643. Also, a pixel defining layer 635 is formed to cover the first electrode 661. An opening 664 is formed in the pixel defining layer 635, and then, the intermediate 663 including an organic emission layer is formed in an area defined by the opening 664. The second electrode 662 is formed on the intermediate layer 663.

An encapsulation layer 670 is formed on the second electrode 662. The encapsulation layer 670 may contain an organic material or an inorganic material and may have a structure formed by alternately depositing the organic material and inorganic material.

The encapsulation layer 670 may be formed by using the vapor deposition apparatus 100. That is, a desired layer may be formed by allowing the substrate 630 formed with the second electrode 662 to pass through the vapor deposition apparatus 100.

Particularly, the encapsulation layer 670 includes an inorganic layer 671 and an organic layer 672. The inorganic layer 671 includes a plurality of layers 671a, 671b, and 671c, and the organic layer 672 includes a plurality of layers 672a, 672b, and 672c. In this case, the plurality of layers 671a, 671b, and 671c of the inorganic layer 671 may be formed by using the vapor deposition apparatus 100.

However, the present embodiment is not limited thereto. That is, other insulating layers of the organic light emitting display apparatus 600 such as the buffer layer 631, the gate insulating layer 632, the interlayer dielectric 633, the passivation layer 634, and the pixel defining layer 635 may be formed by using the vapor deposition apparatus 100.

Also, other various thin films such as the active layer 641, the gate electrode 642, the source/drain electrodes 643, the first electrode 661, the intermediate layer 663, and the second electrode 662 may also be formed by using the vapor deposition apparatus 100.

Since elements shown in the drawings may be shown as being expanded or contracted for convenience of description, the present embodiment is not limited to sizes or shapes of the elements shown in the drawings and it may be understood by a person with ordinary skill that various modifications and other equivalent embodiments may be available therefrom. Accordingly, true technical scope of the present invention will be determined by technical thoughts of attached claims.

As described above, according to the one or more of the above embodiments of the present invention, a vapor deposition apparatus may reduce a length of a chamber thereof.

Also, since a deposition unit intermittently supplies a raw material gas, an amount of a consumed raw material gas may be reduced, thereby increasing durability of a nozzle.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. A vapor deposition apparatus comprising:
a deposition unit comprising a plurality of deposition modules disposed parallel to each other; and
a substrate mounting unit configured to face the deposition unit, the substrate mounting unit configured to mount a substrate,
wherein each of the plurality of deposition modules comprises a nozzle configured to selectively inject a raw gas and a purge gas toward the substrate mounting unit, and
wherein the nozzle is configured to inject the raw gas while the substrate mounting unit faces the nozzle.

2. The vapor deposition apparatus of claim 1, further comprising an inflow pipe, a discharge pipe, and a switch unit,
wherein one end of the nozzle is connected to the inflow pipe and another end of the nozzle is connected to the discharge pipe, and
wherein the inflow pipe is connected to the switch unit, the switch unit configured to selectively supply the raw gas and the purge gas to the inflow pipe.

3. The vapor deposition apparatus of claim 2, further comprising
a discharge valve provided on the discharge pipe, the discharge valve configured to be open while the purge gas is being supplied to the nozzle.

4. The vapor deposition apparatus of claim 3, wherein the switch unit comprises a raw gas pipe connected to the inflow pipe and a purge gas pipe,
wherein a raw gas valve is disposed on the raw gas pipe and is configured to block a flow of the raw gas and a purge gas valve is disposed on the purge gas pipe and is configured to block a flow of the purge gas, and
wherein the raw gas valve and the purge gas valve are configured to alternately operate.

5. The vapor deposition apparatus of claim 4, wherein the switch unit further comprises a first vent pipe diverged from the raw gas pipe and a second vent pipe diverged from the purge gas pipe.

6. The vapor deposition apparatus of claim 5, wherein a first valve is disposed on the first vent pipe and a second valve is disposed on the second vent pipe,
wherein the first valve and the raw gas valve are configured to alternately operate, and
wherein the second valve and the purge gas valve are configured to alternately operate.

7. The vapor deposition apparatus of claim 3, wherein the switch unit comprises a purge gas pipe connected to the inflow pipe and a first pipe and a second pipe diverged and extended from the purge gas pipe, and
wherein the first pipe and the second pipe are connected to a canister configured to supply the raw gas to the inflow pipe.

8. The vapor deposition apparatus of claim 7, wherein a purge gas valve is disposed on the purge gas pipe to block a flow of the purge gas, and
wherein the purge gas valve is disposed between the first pipe and the second pipe.

9. The vapor deposition apparatus of claim 8, wherein with a first valve is disposed on the first pipe and a second valve is disposed on the second pipe, and
wherein the first valve and the second valve operate contrary to the purge gas valve and the discharge valve.

10. The vapor deposition apparatus of claim 3, wherein the substrate mounting unit is configured to reciprocate below the deposition unit, the vapor deposition apparatus further comprising a sensor unit configured to sense a position of the substrate mounting unit and a control unit configured to receive position information of the substrate mounting unit from the sensor unit.

11. The vapor deposition apparatus of claim 10, wherein the control unit is configured to control operations of the switch unit and the discharge valve according to the position information.

12. The vapor deposition apparatus of claim 1, wherein the nozzle comprises a first nozzle configured to selectively inject a first raw gas of the raw gas and the purge gas toward the substrate mounting unit and a second nozzle configured to selectively inject a second raw gas of the raw gas and the purge gas toward the substrate mounting unit.

13. The vapor deposition apparatus of claim 12, wherein each of the plurality of deposition modules further comprises a discharge part and a purge part between the first nozzle and the second nozzle.

14. A vapor deposition apparatus comprising:
a deposition unit comprising a plurality of deposition modules disposed parallel to each other;
a substrate mounting unit configured to face the deposition unit, the substrate mounting unit configured to mount a substrate;
a sensor unit configured to sense a position of the substrate mounting unit; and
a control unit configured to receive position information of the substrate mounting unit from the sensor unit,
wherein each of the plurality of deposition modules comprises a nozzle configured to selectively inject a raw gas and a purge gas toward the substrate mounting unit,
wherein one end of the nozzle is connected to a switch unit configured to selectively supply the raw gas and the purge gas, and
wherein the control unit is configured to control an operation of the switch unit according to the position information.

15. The vapor deposition apparatus of claim 14, further comprising a discharge pipe,
wherein another end of the nozzle is connected to the discharge pipe that includes a discharge valve, and
wherein the control unit is configured to control an operation of the discharge valve according to the position information.

16. The vapor deposition apparatus of claim 15, wherein the nozzle is configured to inject the raw gas when the substrate mounting unit faces the nozzle.

17. The vapor deposition apparatus of claim 15, wherein the discharge valve is configured to be open while the nozzle is injecting the purge gas.

18. The vapor deposition apparatus of claim 14, wherein the substrate mounting unit is configured to reciprocate below the deposition unit.

19. The vapor deposition apparatus of claim 14, wherein the nozzle comprises a first nozzle configured to selectively inject a first raw gas and the purge gas toward the substrate mounting unit and a second nozzle configured to selectively inject a second raw gas and the purge gas toward the substrate mounting unit.

20. The vapor deposition apparatus of claim 19, wherein each of the plurality of deposition modules further comprises an exhaust part and a purge part disposed between the first nozzle and the second nozzle.
